(19) United States
(12) Patent Application Publication
(10) Pub. No.: US 2016/0343703 A1
(43) Pub. Date: Nov. 24, 2016

(54) SEMICONDUCTOR DEVICES HAVING STUD PATTERNS THAT ARE ALIGNED AND MISALIGNED WITH CONTACT PATTERNS

(71) Applicants: BYUNGJOO GO, HWASEONG-SI (KR); HONGSOO KIM, SEONGNAM-SI (KR)

(72) Inventors: BYUNGJOO GO, HWASEONG-SI (KR); HONGSOO KIM, SEONGNAM-SI (KR)

(21) Appl. No.: 15/002,679

(22) Filed: Jan. 21, 2016

(30) Foreign Application Priority Data
May 21, 2015 (KR) 10-2015-0071158

(51) Int. Cl. H01L 27/088; H01L 27/02; H01L 29/417; H01L 23/528; H01L 29/423

(52) U.S. Cl. CPC H01L 27/088; H01L 23/528; H01L 29/42372; H01L 29/41758; H01L 27/0207

(57) ABSTRACT

A semiconductor device includes an active region, a gate pattern on the active region, the active region including a source region at a first side of the gate pattern and a drain region at a second side of the gate pattern, a gate contact pattern on the gate pattern and a drain contact pattern on the drain region, and a gate stud pattern on the gate contact pattern and a drain stud pattern on the drain contact pattern. A distance between a gate contact axis passing through a center portion of the gate contact pattern and a drain contact axis passing through a center portion of the drain contact pattern is different from a distance between a gate stud axis passing through a center portion of the gate stud pattern and a drain stud axis passing through a center portion of the drain stud pattern.

### CROSS-REFERENCE TO RELATED APPLICATION

This application claims priority under 35 U.S.C. §119 to Korean Patent Application No. 10-2015-0071158 filed on May 21, 2015, the disclosure of which is incorporated by reference herein in its entirety.

### TECHNICAL FIELD

Exemplary embodiments of the inventive concept relate to semiconductor devices having aligned and misaligned stud patterns.

### DESCRIPTION OF RELATED ART

With an increase in the integration density of semiconductor devices, comes an increase in heights of contact patterns. When the heights of the contact patterns increase, gradients of sidewalls of the contact patterns are increased. Thus, greater align margins to form metal lines on the contact patterns are needed. Accordingly, horizontal pitches, intervals, or sizes of the contact patterns, the metal lines, and the active regions are increased.

### SUMMARY

Exemplary embodiments of the inventive concept provide a semiconductor device having contact patterns and aligned and misaligned stud patterns.

Exemplary embodiments of the inventive concept provide a semiconductor device having an active region whose size is reduced.

In accordance with an exemplary embodiment of the inventive concept, a semiconductor device includes an active region, a gate pattern on the active region, the active region including a source region at a first side of the gate pattern and a drain region at a second side of the gate pattern, a gate contact pattern on the gate pattern and a drain contact pattern on the drain region, and a gate stud pattern on the gate contact pattern and a drain stud pattern on the drain contact pattern. A distance between a gate contact axis passing through a center portion of the gate contact pattern in a first direction and a drain contact axis passing through a center portion of the drain contact pattern in the first direction may be different from a distance between a gate stud axis passing through a center portion of the gate stud pattern in the first direction and a drain stud axis passing through a center portion of the drain stud pattern in the first direction. The first direction may be substantially perpendicular to a surface of the active region on which the gate pattern is disposed.

The semiconductor device may further include a gate metal line on the gate stud pattern and a drain metal line on the drain stud pattern. A distance between a gate metal axis passing through a center portion of the gate metal line in the first direction and a drain metal axis passing through a center portion of the drain metal line in the first direction may be greater than a distance between the gate contact axis and the drain contact axis.

The semiconductor device may further include a source contact pattern on the source region, and a source stud pattern on the source contact pattern. A distance between the gate contact axis and a source contact axis passing through a center portion of the source contact pattern in the first direction may be less than a distance between the gate stud axis and a source stud axis passing through a center portion of the source stud pattern in the first direction.

The semiconductor device may further include a source metal line on the source stud pattern. A distance between the gate metal axis and a source metal axis passing through a center portion of the source metal line in the first direction may be greater than a distance between the gate contact axis and the source contact axis.

A distance between the gate stud axis and the source stud axis may be substantially the same as a distance between the gate metal axis and the source metal axis.

The gate stud axis may be substantially aligned with the gate metal axis in the first direction.

The source contact axis may not be aligned with the source stud axis in the first direction.

The source stud axis may be substantially aligned with the source metal axis in the first direction, and the drain stud axis may be substantially aligned with the drain metal axis in the first direction.

A distance between the gate stud axis and the drain stud axis may be substantially the same as a distance between the gate metal axis and the drain metal axis.

The gate contact axis may be substantially aligned with the gate stud axis in the first direction. The drain contact axis may not be aligned with the drain stud axis in the first direction.

In accordance with an exemplary embodiment of the inventive concept, a semiconductor device includes a first active region and a second active region, a first gate pattern on the first active region including a first source region and a first drain region and a second gate pattern on the second active region including a second source region and a second drain region, a first gate contact pattern on the first gate pattern, a first source contact pattern on the first source region, a first drain contact pattern on the first drain region, a second gate contact pattern on the second gate pattern, a second source contact pattern on the second source region, and a second drain contact pattern on the second drain region, and a first gate stud pattern on the first gate contact pattern, a first source stud pattern on the first source contact pattern, a first drain stud pattern on the first drain contact pattern, a second gate stud pattern on the second gate contact pattern, a second source stud pattern on the second source contact pattern, and a second drain stud pattern on the second drain contact pattern. A distance between a drain contact axis passing through a center portion the first drain contact pattern in a first direction and a source contact axis passing through a center portion of the second source contact pattern in the first direction may be different from a distance between a drain stud axis passing through a center portion of the first drain stud pattern in the first direction and a source stud axis passing through a center portion of the second source stud pattern in the first direction. The first direction may be substantially perpendicular to a surface of the first and second active regions on which the first and second gate patterns are disposed.

The semiconductor device may further include a first gate metal line on the first gate stud pattern, a first source metal line on the first source stud pattern, a first drain metal line on the first drain stud pattern, a second gate metal line on the second gate stud pattern, a second source metal line on the second source stud pattern, and a second drain metal line on the second drain stud pattern. A distance between the first drain metal line and the second source metal line may be less than a distance between the first active region and the second active region.

A distance between a drain metal axis passing though a center portion of the first drain metal line in the first direction and a source metal axis passing through a center portion of the second source metal line in the first direction may be greater than a distance between the drain contact axis and the source contact axis.

A distance between the drain stud axis and the source stud axis may be substantially the same as a distance between the drain metal axis and the source metal axis.

A distance between a first gate contact axis passing through a center portion of the first gate contact pattern in the first direction and a second gate contact axis passing through a center portion of the second gate contact pattern in the first direction may be substantially the same as a distance between a first gate stud axis passing through a center portion of the first gate stud pattern in the first direction and a second gate stud axis passing through a center portion of the second gate stud pattern in the first direction.

In accordance with an exemplary embodiment of the inventive concept, a semiconductor device includes: a source contact pattern, a gate contact pattern and a drain contact pattern sequentially arranged in a first direction; and a source stud pattern disposed on the source contact pattern, a gate stud pattern disposed on the gate contact pattern and a drain stud pattern disposed on the drain contact pattern, wherein a first side of the source contact pattern, a second side of the source contact pattern, a first side of the drain contact pattern and a second side of the drain contact pattern are sequentially arranged in the first direction, and wherein the source stud pattern is disposed adjacent to the first side of the source contact pattern and the drain stud pattern is disposed adjacent to the second side of the drain contact pattern.

An axis passing through a central portion of the source contact pattern in a second direction substantially perpendicular to the first direction may not be aligned with an axis passing through a central portion of the source stud pattern in the second direction.

An axis passing through a central portion of the drain contact pattern in a second direction substantially perpendicular to the first direction may not be aligned with an axis passing through a central portion of the drain stud pattern in the second direction.

The semiconductor device may be a metal-oxide-semiconductor (MOS) transistor.

The MOS transistor may be disposed in a peripheral area of a circuit.

### BRIEF DESCRIPTION OF THE DRAWINGS

The foregoing and other features of the inventive concept will become more apparent by describing in detail exemplary embodiments thereof with reference to the accompanying drawings. In the drawings:

FIG. 1A is a layout of a semiconductor device in accordance with an exemplary embodiment of the inventive concept;

FIG. 1B is a cross sectional view taken along line I-I′ of FIG. 1A;

FIG. 1C is a enlarged view of area A of FIG. 1B;

FIG. 1D is an enlarged view of area B of FIG. 1B;

FIG. 2A is a layout of a semiconductor device in accordance with an exemplary embodiment of the inventive concept;

FIG. 2B is a cross sectional view taken along line II-II′ of FIG. 2A;

FIG. 3A is a layout of a semiconductor device in accordance with an exemplary embodiment of the inventive concept;

FIG. 3B is a cross sectional view taken along line III-III′ of FIG. 3A.

FIG. 4A is a layout of a semiconductor device in accordance with an exemplary embodiment of the inventive concept;

FIG. 4B is a cross sectional view taken along line IV-IV′ of FIG. 4A;

FIG. 4C is an enlarged view of area C of FIG. 4B;

FIG. 5A is a layout of a semiconductor device in accordance with an exemplary embodiment of the inventive concept;

FIG. 5B is a cross sectional view taken along line V-V′ of FIG. 5A;

FIG. 6A is a layout of a semiconductor device in accordance with an exemplary embodiment of the inventive concept;

FIG. 6B is a cross sectional view taken along line VI-VI′ of FIG. 6A;

FIG. 7A is a layout of a semiconductor device in accordance with an exemplary embodiment of the inventive concept;

FIG. 7B is a cross sectional view taken along line VII-VII′ of FIG. 7A;

FIG. 7C is an enlarged view of area D of FIG. 7B;

FIG. 8A is a layout of a semiconductor device in accordance with an exemplary embodiment of the inventive concept;

FIG. 8B is a cross sectional view taken along line VIII-VIII′ of FIG. 8A;

FIG. 9A is a layout of a semiconductor device in accordance with an exemplary embodiment of the inventive concept;

FIG. 9B is a cross sectional view taken along line IX-IX′ of FIG. 9A;

FIG. 10A is a diagram showing a memory module in accordance with an exemplary embodiment of the inventive concept;

FIG. 10B is a diagram showing a semiconductor module in accordance with an exemplary embodiment of the inventive concept;

FIG. 10C is a block diagram showing an electronic system in accordance with an exemplary embodiment of the inventive concept; and

FIG. 10D is a block diagram showing an electronic system in accordance with an exemplary embodiment of the inventive concept.

### DETAILED DESCRIPTION OF THE EMBODIMENTS

Exemplary embodiments of the present inventive concept will now be described in detail with reference to the accompanying drawings. The inventive concept may, however, be embodied in many different forms and should not be construed as being limited to the embodiments set forth herein.

The articles “a,” “an,” and “the” are singular in that they have a single referent; however, the use of the singular form in the present document should not preclude the presence of more than one referent. In other words, elements of the inventive concept referred to in the singular form may number one or more, unless the context clearly indicates otherwise.

When one element (elements) is (are) referred to as “connected” or “coupled” to other element(s), this may indicate directly connected or coupled to the elements(s), or intervening elements may be present.

Exemplary embodiments of the inventive concept are described herein with reference to cross-sectional and/or planar illustrations that are schematic illustrations of idealized embodiments and intermediate structures. In the drawings, the sizes and relative sizes of layers and regions may be exaggerated for clarity. As such, variations from the shapes of the illustrations as a result, for example, of manufacturing techniques and/or tolerances, are to be expected. Thus, the embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from an implanted to a non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Like numerals refer to like elements throughout the specification. Accordingly, the same numerals and similar numerals can be described with reference to other drawings, even if not specifically described in a corresponding drawing. Further, when a numeral is not marked in a drawing, the numeral can be described with reference to other drawings.

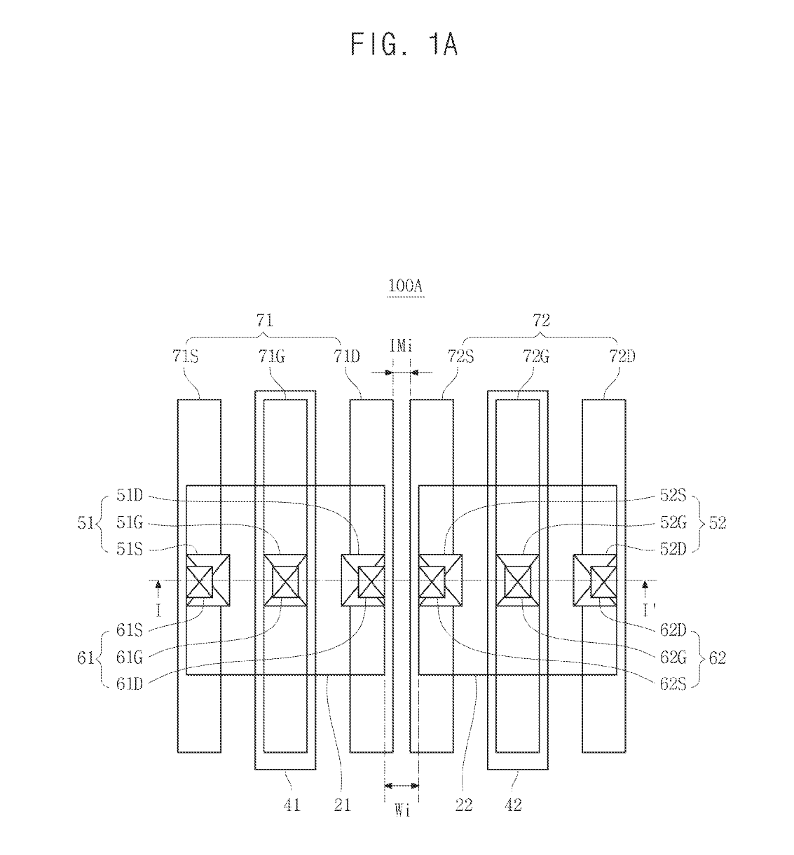

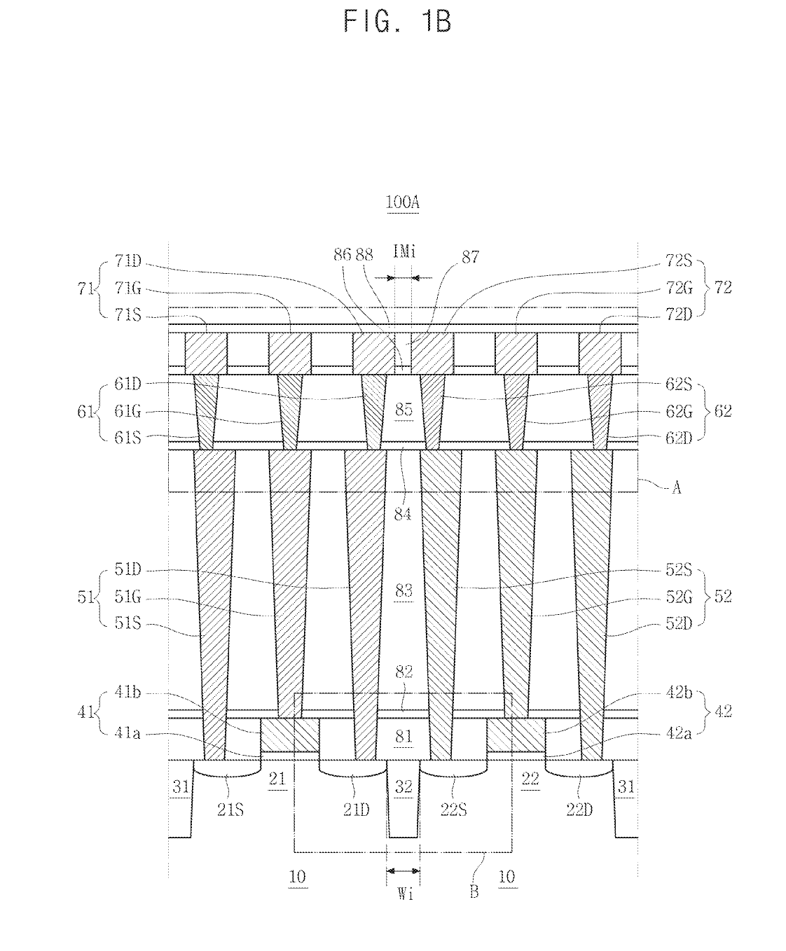

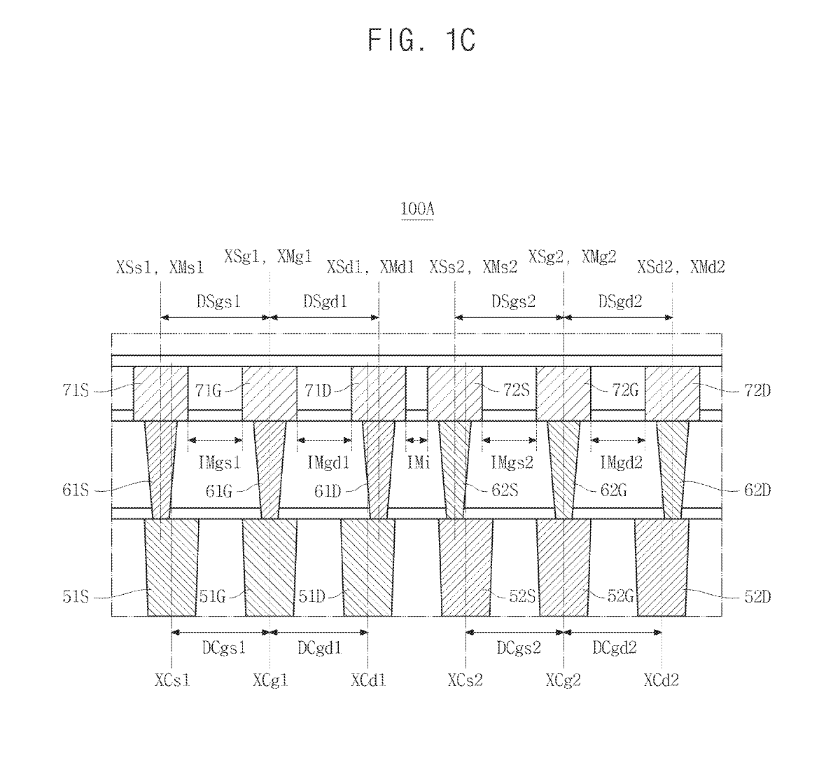

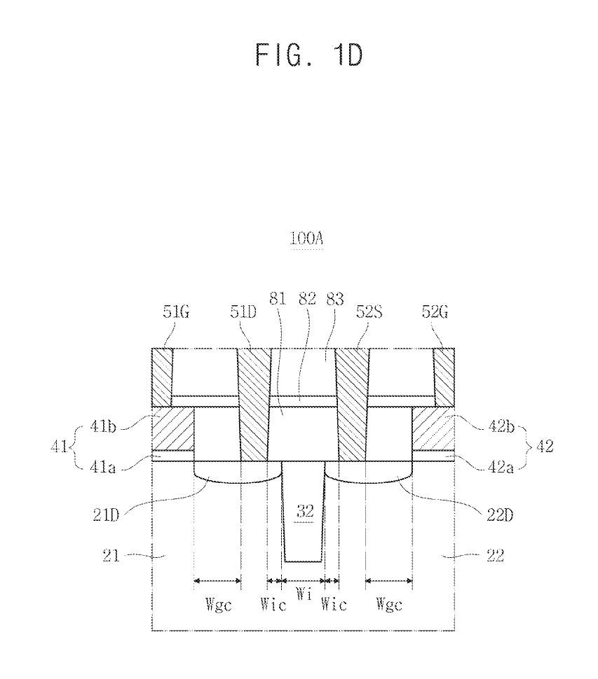

FIG. 1A is a layout of a semiconductor device in accordance with an exemplary embodiment of the inventive concept, FIG. 1B is a cross sectional view taken along line I-I′ of FIG. 1A, FIG. 1C is an enlarged view of area A of FIG. 1B, and FIG. 1D is an enlarged view of area B of FIG. 1B.

Referring to FIGS. 1A and 1B, a semiconductor device 100A in accordance with an exemplary embodiment of the concept may include isolation regions 31 and 32 defining active regions 21 and 22 on a substrate 10, gate patterns 41 and 42 across the active regions 21 and 22, contact patterns 51 and 52, stud patterns 61 and 62, and metal lines 71 and 72.

The substrate 10 may include a single crystalline silicon wafer, a silicon-on-insulator (SOI) wafer, a SiGe grown on a Si wafer, or other semiconductor substrates.

The isolation regions 31 and 32 may surround sidewalls of the active regions 21 and 22. The isolation regions 31 and 32 may include isolation trenches and an isolation insulating material filled in the isolation trenches. The isolation insulating material may include silicon oxide (SiO2). The isolation regions 31 and 32 may include outer isolation regions 31 surrounding outsides of the active regions 21 and 22 and inter-active isolation region 32 between the active regions 21 and 22.

The active regions 21 and 22 may include a first active region 21 and a second active region 22 adjacent to each other. The first active region 21 and the second active region 22 may include source regions 21S and 22S, and drain regions 21D and 22D at both sides of the gate patterns 41 and 42, respectively. For example, the first active region 21 may include a first source region 21S and a first drain region 21D, and the second active region 22 may include a second source region 22S and a second drain region 22D. The active regions 21 and 22 may be a doped portion of the substrate 10.

The gate patterns 41 and 42 may include a first gate pattern 41 on the first active region 21 and a second gate pattern 42 on the second active region 22. The first gate pattern 41 may cross the first active region 21 to define the first source region 21S and the first drain region 21D, and the second gate pattern 42 may cross the second active region 22 to define the second source region 22S and the second drain region 22D. The first gate pattern 41 and the second gate pattern 42 may include gate insulating layers 41a and 42a, and gate electrodes 41b and 42b, respectively. The gate insulating layers 41a and 42a may include silicon oxide (SiO2) or a metal oxide. The metal oxide may include hafnium oxide, aluminum oxide, titanium oxide, or other metal oxides. The gate electrodes 41b and 42b may include a metal such as tungsten (W) or copper (Cu).

The contact patterns 51 and 52 may include first contact patterns 51 and second contact patterns 52. The first contact patterns 51 may include a first gate contact pattern 51G, a first source contact pattern 51S, and a first drain contact pattern 51D, and the second contact patterns 52 may include a second gate contact pattern 52G, a second source contact pattern 52S, and a second drain contact pattern 52D. The first gate contact pattern 51G may be disposed on the first gate pattern 41 to be electrically connected with the first gate pattern 41, and the second gate contact pattern 52G may be disposed on the second gate pattern 42 to be electrically connected with the second gate pattern 42. The first source contact pattern 51S may be disposed on the first source region 21S to be electrically connected with the first source region 21S, and the second source contact pattern 52S may be disposed on the second source region 22S to be electrically connected with the second source region 22S. The first drain contact pattern 51D may be disposed on the first drain region 21D to be electrically connected with the first drain region 21D, and the second drain contact pattern 52D may be disposed on the second drain region 22D to be electrically connected with the second drain region 22D. The contact patterns 51 and 52 may include a metal such as tungsten (W) or copper (Cu).

The stud patterns 61 and 62 may include first stud patterns 61 and second stud patterns 62. The first stud patterns 61 may include a first gate stud pattern 61G, a first source stud pattern 61S, and a first drain stud pattern 61D, and the second stud patterns 62 may include a second gate stud pattern 62G, a second source stud pattern 62S, and a second drain stud pattern 62D. The first gate stud pattern 61G may be disposed on the first gate contact pattern 51G to be electrically connected with the first gate contact pattern 51G, and the second gate stud pattern 62G may be disposed on the second gate contact pattern 52G to be electrically connected with the second gate contact pattern 52G. The first source stud pattern 61S may be disposed on the first source contact pattern 51S to be electrically connected with the first source contact pattern 51S, and the second source stud pattern 62S may be disposed on the second source contact pattern 52S to be electrically connected with the second source contact pattern 52S. The first drain stud pattern 61D may be disposed on the first drain contact pattern 51D to be electrically connected with the first drain contact pattern 51D, and the second drain stud pattern 62D may be disposed on the second drain contact pattern 52D to be electrically connected with the second drain contact pattern 52D. The stud patterns 61 and 62 may include a metal such as tungsten (W) or copper (Cu).

The metal lines 71 and 72 may include first metal lines 71 and second metal lines 72. The first metal lines 71 may include a first gate metal line 71G, a first source metal line 71S, and a first drain metal line 71D, and the second metal lines 72 may include a second gate metal line 72G, a second source metal line 72S, and a second drain metal line 72D. The first gate metal line 71G may be disposed on the first gate stud pattern 61G to be electrically connected with the first gate stud pattern 61G, and the second gate metal line 72G may be disposed on the second gate stud pattern 62G to be electrically connected with the second gate stud pattern 62G. The first source metal line 71S may be disposed on the first source stud pattern 61S to be electrically connected with the first source stud pattern 61S, and the second source metal line 72S may be disposed on the second source stud pattern 62S to be electrically connected with the second source stud pattern 62S. The first drain metal line 71D may be disposed on the first drain stud pattern 61D to be electrically connected with the first drain stud pattern 61D, and the second drain metal line 72D may be disposed on the second drain stud pattern 62D to be electrically connected with the second drain stud pattern 62D.

The metal lines 71 and 72 may include a metal such as tungsten (W) or copper (Cu). The semiconductor device 100A may further include a lower interlayer insulating layer 81 coplanar with the first and second gate patterns 41 and 42. The lower interlayer insulating layer 81 may include silicon oxide (SiO2). The first and second source contact patterns 51S and 52S, and the first and second drain contact patterns 51D and 52D may vertically penetrate the lower interlayer insulating layer 81.

The semiconductor device 100A may further include a lower stopper layer 82 on the first and second gate patterns 41 and 42, and the lower interlayer insulating layer 81. The lower stopper layer 82 may include silicon nitride (SiN). Accordingly, the first and second gate contact patterns 51G and 52G, the first and second source contact patterns 51S and 52S, and the first and second drain contact patterns 51D and 52D may vertically penetrate the lower stopper layer 82.

The semiconductor device 100A may further include a middle interlayer insulating layer 83 on the lower stopper layer 82. The middle interlayer insulating layer 83 and the first and second contact patterns 51 and 52 may be coplanar. The middle interlayer insulating layer 83 may include silicon oxide (SiO₂). The first and second gate contact patterns 51G and 52G, the first and second source contact patterns 51S and 52S, and the first and second drain contact patterns 51D and 52D may vertically penetrate the middle interlayer insulating layer 83.

The semiconductor device 100A may further include a middle stopper layer 84 on the first and second contact patterns 51 and 52, and the middle interlayer insulating layer 83. The middle stopper layer 84 may include silicon nitride (SiN).

The semiconductor device 100A may further include an upper interlayer insulating layer 85 on the middle stopper layer 84. The upper interlayer insulating layer 85 and the first and second stud patterns 61 and 62 may be coplanar. The upper interlayer insulating layer 85 may include silicon oxide (SiO₂). The first and second gate stud patterns 61G and 62G, the first and second source stud patterns 61S and 62S, and the first and second drain stud patterns 61D and 62D may vertically penetrate the upper interlayer insulating layer 85 and the middle stopper layer 84.

The semiconductor device 100A may further include an upper stopper layer 86 on the upper interlayer insulating layer 85 and the first and second stud patterns 61 and 62. The upper stopper layer 86 may include silicon nitride (SiN).

The semiconductor device 100A may further include a filling interlayer insulating layer 87 on the upper stopper layer 86. The filling interlayer insulating layer 87 and the first and second metal lines 71 and 72 may be coplanar. The filling interlayer insulating layer 87 may include silicon oxide (SiO2).

The semiconductor device 100A may further include a capping stopper layer 88 on the upper stopper layer 86 and the first and second metal lines 71 and 72. The capping stopper layer 88 may include silicon nitride (SiN).

Referring to FIG. 1C, virtual first and/or second source contact axes XCs1 and/or XCs2 passing through center portions the first and/or second source contact patterns 51S and/or 52S and virtual first and/or second source stud axes XSs1 and/or XSs2 passing through center portions of the first and/or second source stud patterns 61S and/or 62S may not correspond with or not be vertically aligned with each other, respectively. For example, distances DCgs1 and/or DCgs2 between virtual first and/or second gate contact axes XCg1 and/or XCg2 passing through center portions of the first and/or second gate contact patterns 51G and/or 52G and the first and/or second source contact axes XCs1 and/or XCs2 may be less than distances DSgs1 and/or DSgs2 between virtual first and/or second gate stud axes XSg1 and/or XSg2 passing through center portions of the first and/or second gate stud patterns 61G and/or 62G and the first and/or second source stud axes XSs1 and/or XSs2. For example, DCgs1<DSgs1, DCgs2<DSgs2.

The first and/or second source contact axes XCs1 and/or XCs2 and virtual first and/or second drain stud axes XSd1 and/or XSd2 passing through center portions of the first and/or drain stud patterns 61D and/or 62D may not correspond with or not be vertically aligned with each other, respectively. For example, distances DCgd1 and/or DCgd2 between the first and/or second gate contact axes XCg1 and/or XCg2 and first and/or second drain contact axes XCd1 and/or XCd2 may be less than distances DSgd1 and/or DSgd2 between the first and/or second gate stud axes XSg1 and/or XSg2 and the first and/or second drain stud axes XSd1 and/or XSd2. For example, DCgd1<DSgd1, DCgd2<DSgd2.

The distances DCgs1 and/or DCgs2 between the first and/or second gate contact axes XCg1 and/or XCg2 and the first and/or second source contact axes XCs1 and/or XCs2 and/or the distances DCgd1 and/or DCgd2 between the first and/or second gate contact axes XCg1 and/or XCg2 and the first and/or second drain contact axes XCd1 and/or XCd2 may be substantially the same. For example, DCgs1=DCgs2=DCgd1=DCgd2.

Virtual first and/or second gate metal axes XMg1 and/or Xmg2 passing through center portions of the first and/or second gate metal lines 71G and/or 72G may substantially correspond with or be vertically aligned with the first and/or second gate contact axes XCg1 and/or XCg2.

Virtual first and/or second source metal axes XMs1 and/or XMs2 passing through center portions of the first and/or second source metal lines 71S and/or 72S may substantially correspond with or be vertically aligned with the first and/or second source stud axes XSs1 and/or XSs2.

Virtual first and/or second drain metal axes XMd1 and/or XMd2 passing through center portions of the first and/or second drain metal lines 71D and/or 72D may substantially correspond with or be vertically aligned with the first and/or second drain stud axes XSd1 and/or XSd2.

An interval distance IMgs1 between the first gate metal line 71G and the first source metal line 71S, an interval distance IMgd1 between the first gate metal line 71G and the first drain metal line 71D, an interval distance IMgs2 between the second gate metal line 72G and the second source metal line 72S, and an interval distance IMgd2 between the second gate metal line 72G and the second drain metal line 72D may be substantially the same. For example, IMgs1=IMgd1=IMgs2=IMgd2.

The interval distances IMgs1, IMgd1, IMgs2, and IMgd2 may be greater than an interval distance IMi between the first drain metal line 71D and the second source metal line 72S. For example, IMgs1, IMgs2, IMgd1, IMgd2>IMi.

Referring to FIG. 1D, distances Wgc between the first or second gate patterns 41 or 42 and the first or second source contact patterns 51S or 52S, or the first or second gate patterns 41 or 42 and the first or second drain contact patterns 51D or 52D may greater than distances Wic between the inter-active isolation region 32 and the first or second source contact patterns 51S or 52S, or the inter-active isolation region 32 and the first or second drain contact patterns 51D or 52D. For example, Wgc>Wic.

A width Wi of the inter-active isolation region 32 may greater than the interval distance IMi between the first drain metal line 71D and the second source metal line 72S. For example, Wi>IMi. In other words, the width Wi between the first active region 21 and the second active region 22 may greater than the interval distance IMi between the first drain metal line 71D on the first active region 21 and the second source metal line 72S on the second active region 22. For example, Wi>IMi.

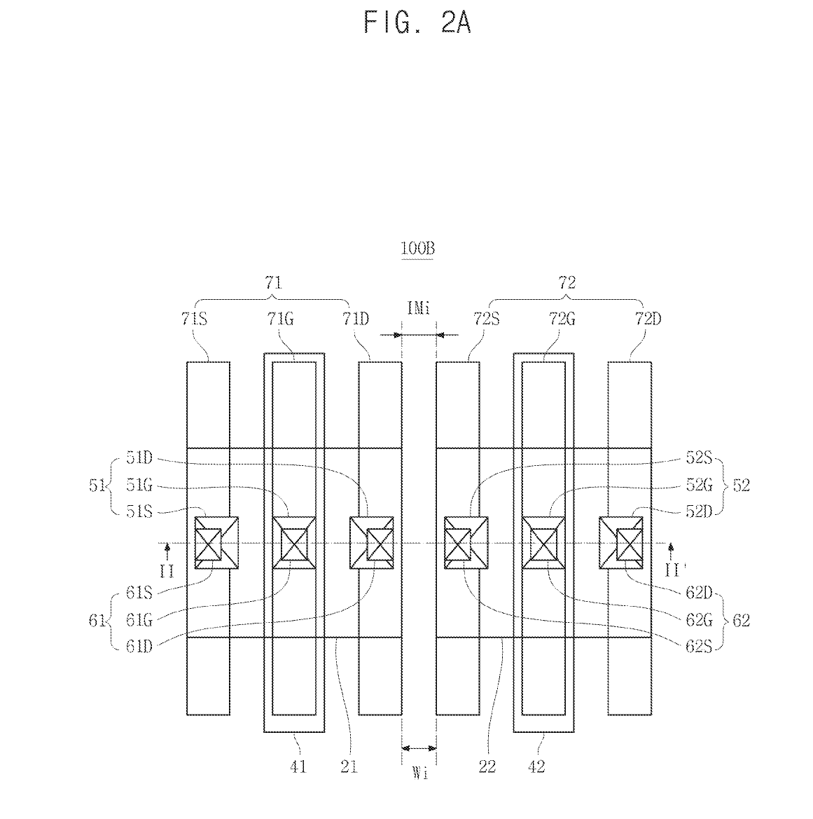

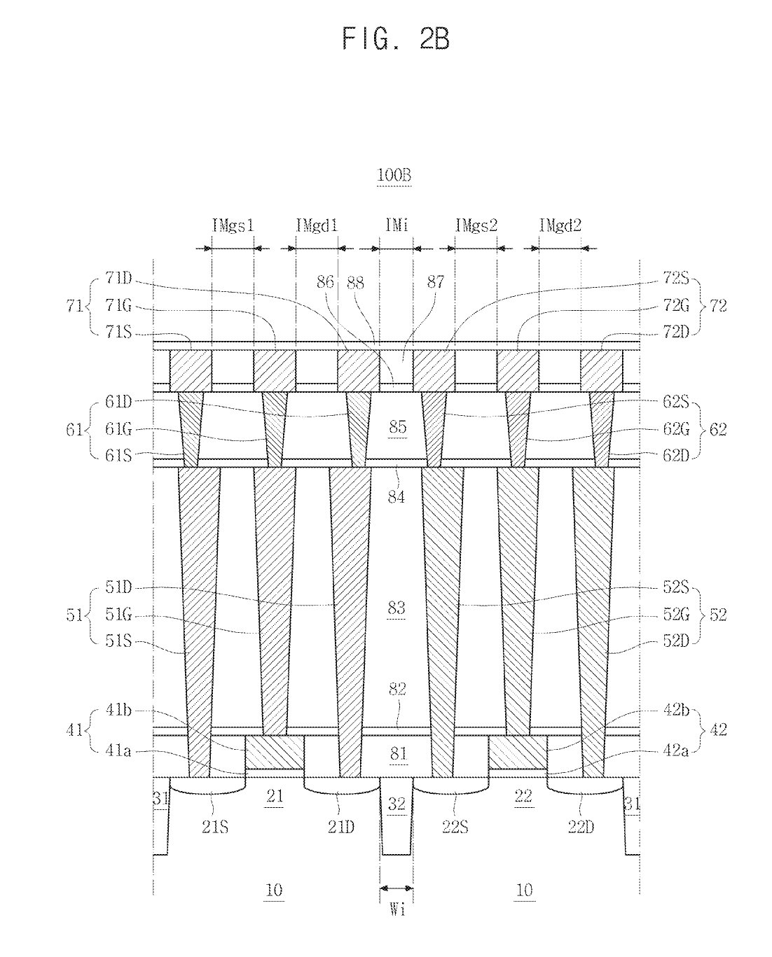

FIG. 2A is a layout of a semiconductor device in accordance with an exemplary embodiment of the inventive concept, and FIG. 2B is a cross sectional view taken along line II-II′ of FIG. 2A. Referring to FIGS. 2A and 2B, a semiconductor device 100B in accordance with an exemplary embodiment of the inventive concept may include outer isolation regions 31 and an inter-active isolation region 32 defining first and second active regions 21 and 22 on a substrate 10, first and second gate patterns 41 and 42 across the first and second active regions 21 and 22, first and second contact patterns 51 and 52, first and second stud patterns 61 and 62, and first and second metal lines 71 and 72. In comparison with the semiconductor device 100A shown in FIGS. 1A to 1D, an interval distance between the first active region 21 and the second active region 22, e.g., the width Wi of the inter-active isolation region 32 may be substantially the same as the interval distance IMi between the first drain metal line 71D and the second source metal line 72S.

An interval distance IMgs1 between the first gate metal line 71G and the first source metal line 71S, an interval distance IMgd1 between the first gate metal line 71G and the first drain metal line 71D, an interval distance IMgs2 between the second gate metal line 72G and the second source metal line 72S, an interval distance IMgd2 between the second gate metal line 72G and the second drain metal line 72D, and an interval distance Imi between the first drain metal line 71D and the second source metal line 72S may be substantially the same. For example, IMgs1=IMgs2=IMgd1=IMgd2=IMi.

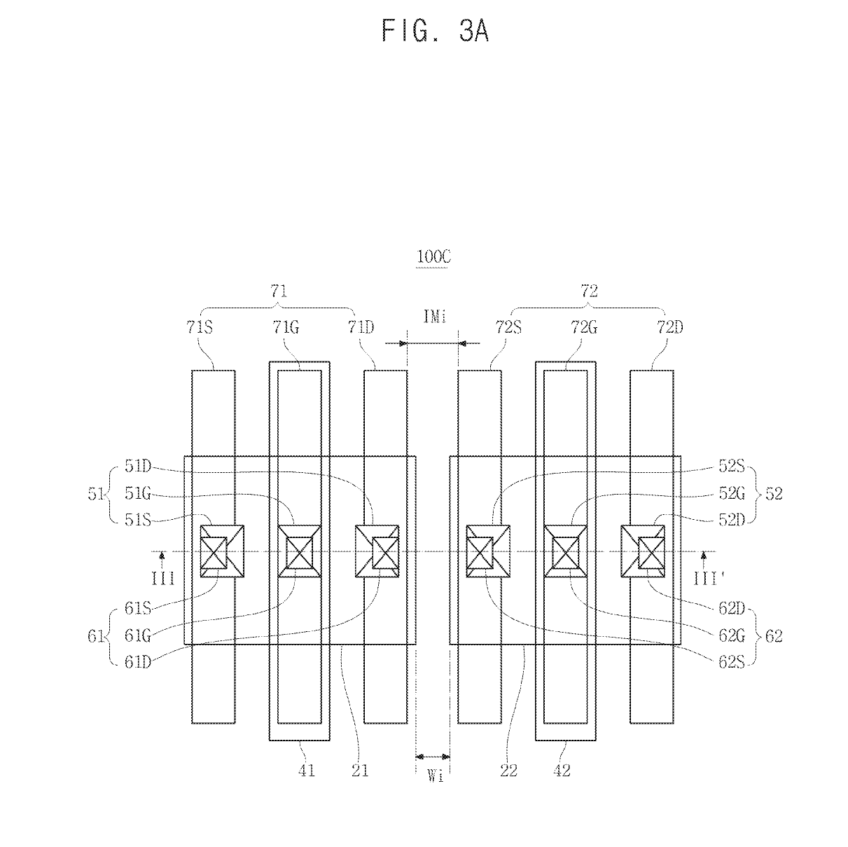

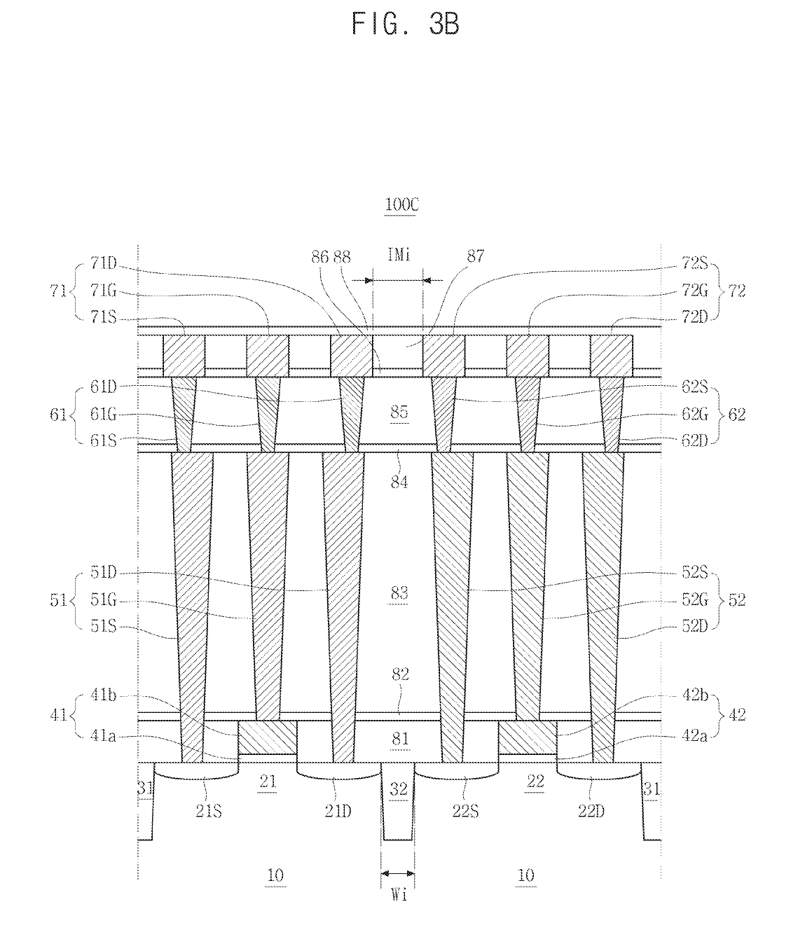

FIG. 3A is a layout of a semiconductor device in accordance with an exemplary embodiment of the inventive concept, and FIG. 3B is a cross sectional view taken along line III-III′ of FIG. 3A. Referring to FIGS. 3A and 3B, a semiconductor device 100C in accordance with an exemplary embodiment of the inventive concept may include outer isolation regions 31 and an inter-active isolation region 32 defining first and second active regions 21 and 22 on a substrate 10, first and second gate patterns 41 and 42 across the first and second active regions 21 and 22, first and second contact patterns 51 and 52, first and second stud patterns 61 and 62, and first and second metal lines 71 and 72. In comparison with the semiconductor device 100A shown FIGS. 1A to 1D, an interval distance between the first active region 21 and the second active region 22, e.g., a width Wi of the inter-active isolation region 32 may be less than an interval distance IMi between the first drain metal line 71D and the second source metal line 72S. For example, Wi<IMi.

In the semiconductor devices 100A, 100B, and 100C shown FIGS. 1A to 3B, widths of the metal lines 71 and 72 and intervals between the metal lines 71 and 72 may be substantially the same.

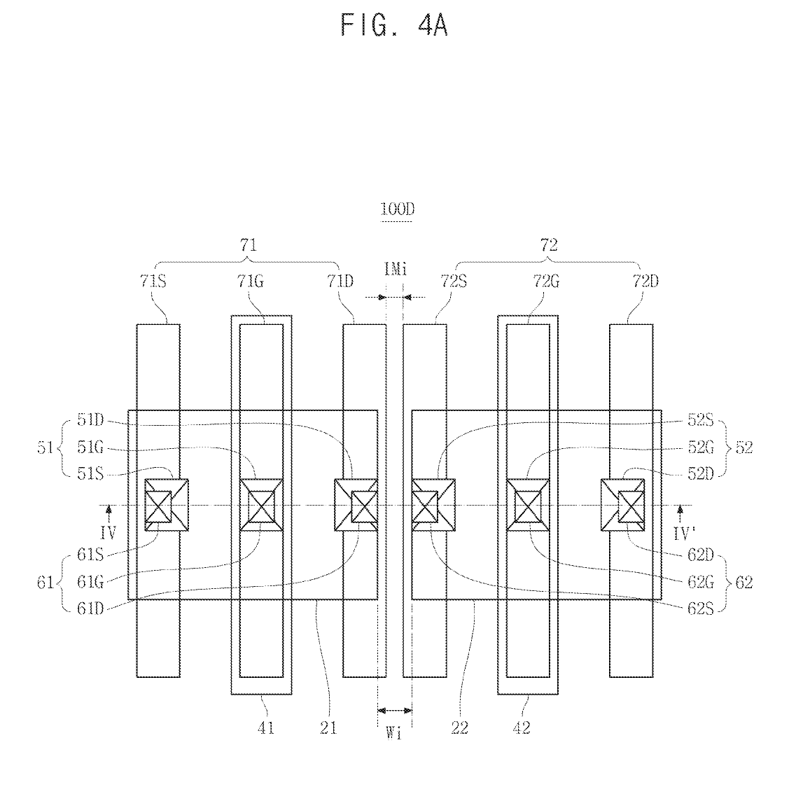

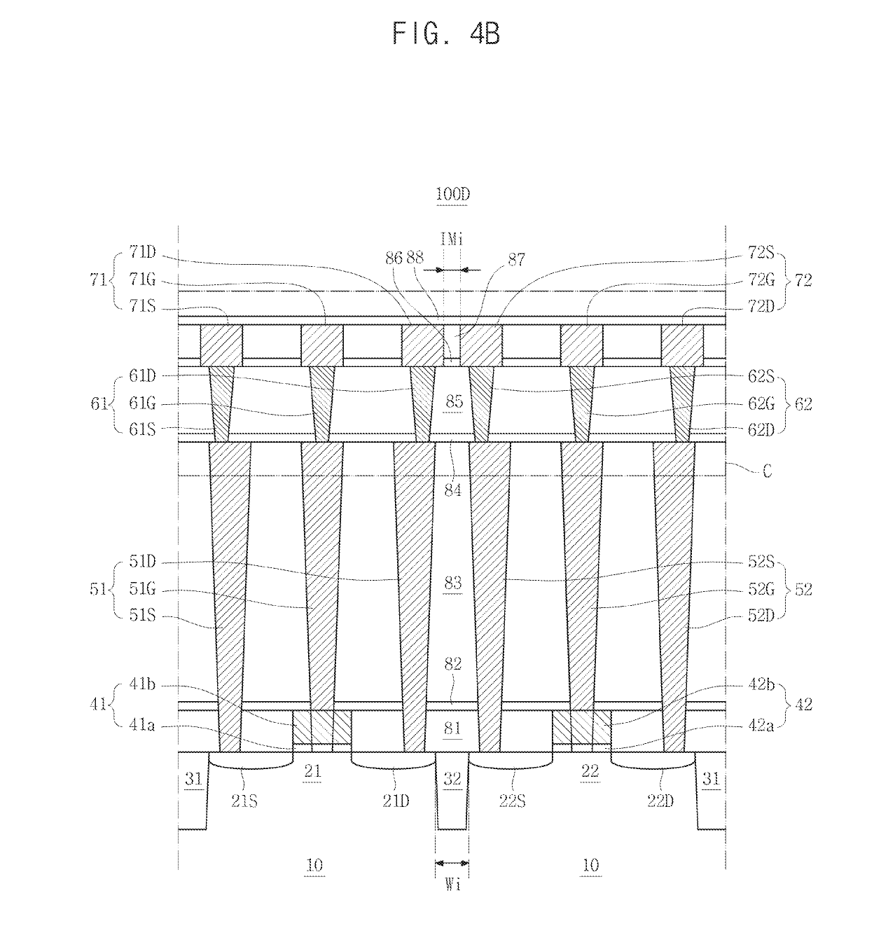

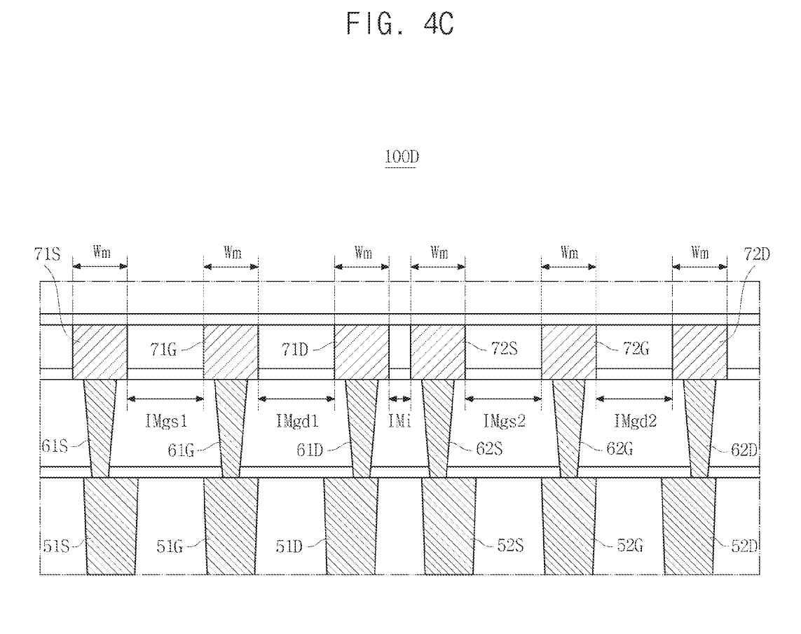

FIG. 4A is a layout of a semiconductor device in accordance with an exemplary embodiment of the inventive concept, FIG. 4B is a cross sectional view taken along line IV-IV′ of FIG. 4A, and FIG. 4C is an enlarged view of area C of FIG. 4B.

Referring to FIGS. 4A, 4B, and 4C, a semiconductor device 100D in accordance with an exemplary embodiment of the inventive concept may include outer isolation regions 31 and an inter-active isolation region 32 defining first and second active regions 21 and 22 on a substrate 10, first and second gate patterns 41 and 42 across the first and second active regions 21 and 22, first and second contact patterns 51 and 52, first and second stud patterns 61 and 62, and first and second metal lines 71 and 72. An interval distance IMgs1 between the first gate metal line 71G and the first source metal line 71S, an interval distance IMgd1 between the first gate metal line 71G and the first drain metal line 71D, an interval distance IMgs2 between the second gate metal line 72G and the second source metal line 72S, and an interval distance IMgd2 between the second gate metal line 72G and the second drain metal line 72D may be substantially the same. For example, IMgs1=IMgd1=IMgs2=IMgd2. The interval distances IMgs1, IMgd1, IMgs2, and IMgd2 between the metal lines 71 and 72 may be greater than an interval distance IMi between the first drain metal line 71D and the second source metal line 71S. For example, IMgs1, IMgs2, IMgd1, IMgd2>IMi.

Widths Wm of the metal lines 71 and 72 may be substantially the same. The interval distance IMgs1 between the first gate metal line 71G and the first source metal line 71S, the interval distance IMgd1 between the first gate metal line 71G and the first drain metal line 71D, the interval distance IMgs2 between the second gate metal line 72G and the second source metal line 72S, and the interval distance IMgd2 between the second gate metal line 72G and the second drain metal line 72D may be greater than the widths Wm of the metal lines 71 and 72. For example, IMgs1, IMgs2, IMgd1, IMgd2>Wm.

An interval distance between the first active region 21 and the second active region 22, e.g., a width Wi of the inter-active isolation region 32 may be less than the interval distance IMi between the first drain metal line 71D and the second source metal line 72S. For example, Wi<IMi.

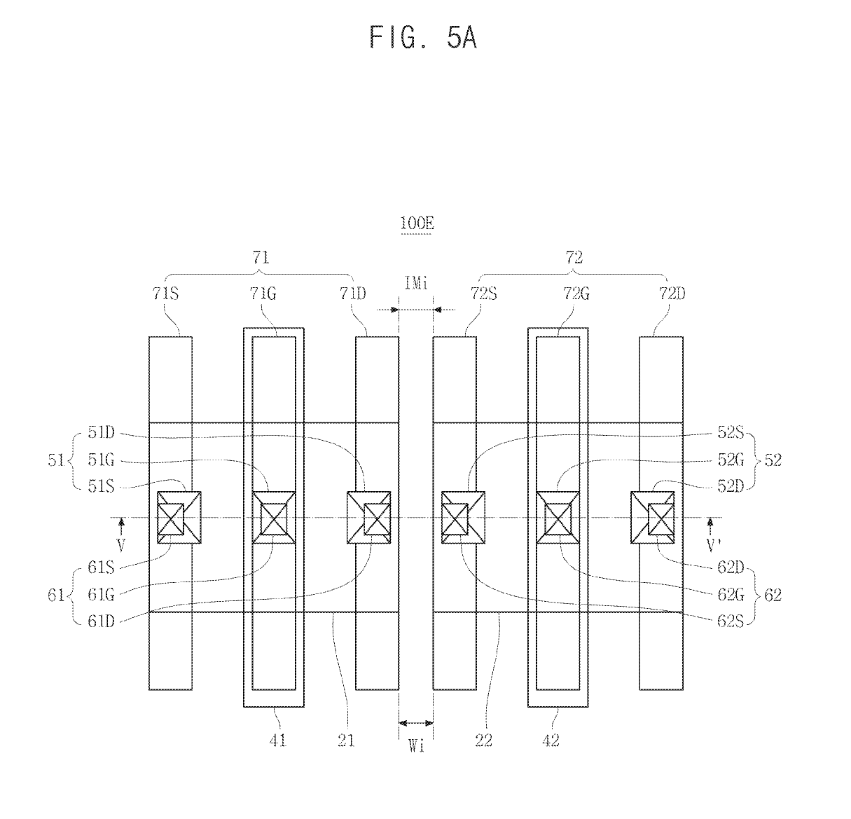

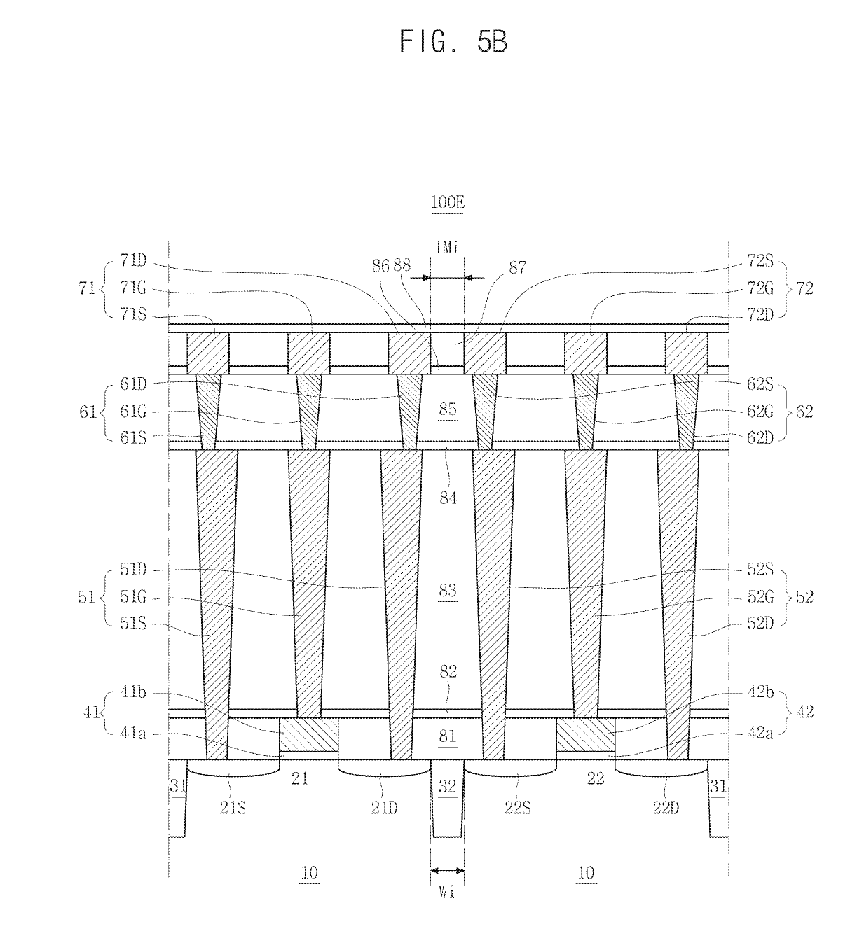

FIG. 5A is a layout of a semiconductor device in accordance with an exemplary embodiment of the inventive concept, and FIG. 5B is a cross sectional view taken along line V-V′ of FIG. 5A. Referring to FIGS. 5A and 5B, a semiconductor device 100E in accordance with an exemplary embodiment of the inventive concept may include outer isolation regions 31 and an inter-active isolation region 32 defining first and second active regions 21 and 22 on a substrate 10, first and second gate patterns 41 and 42 across the first and second active regions 21 and 22, first and second contact patterns 51 and 52, first and second stud patterns 61 and 62, and first and second metal lines 71 and 72. In comparison with the semiconductor device 100D shown in FIGS. 4A to 4C, an interval distance between the first active region 21 and the second active region 22, e.g., a width Wi of the inter-active isolation region 32 may be substantially the same as an interval distance IMi between the first metal line 71D and the second source metal line 72S. For example, Wi=IMi.

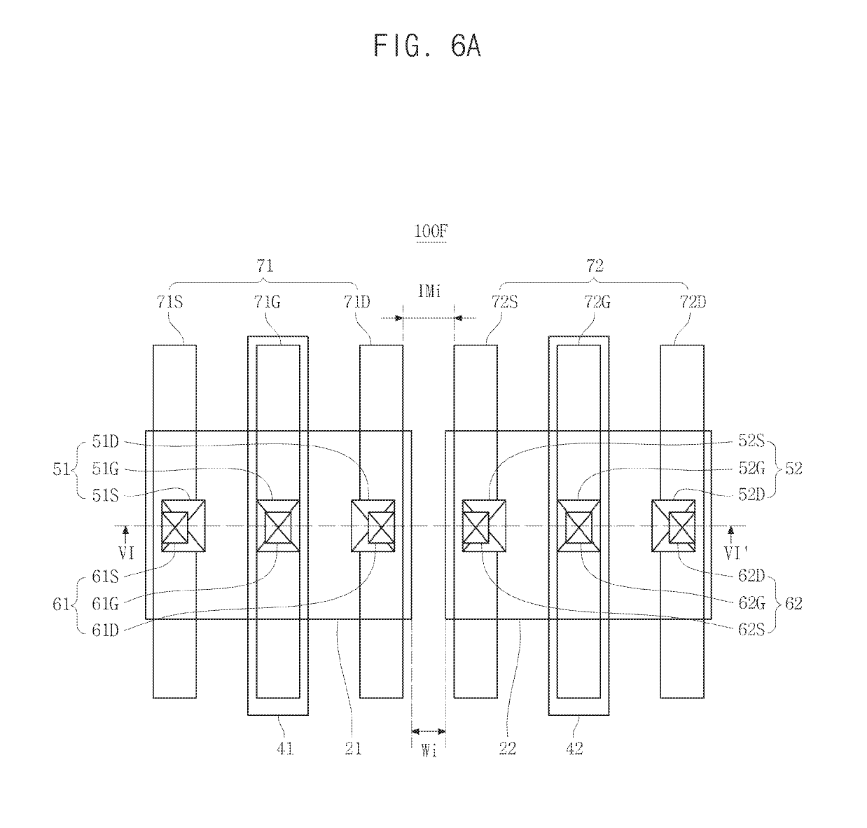

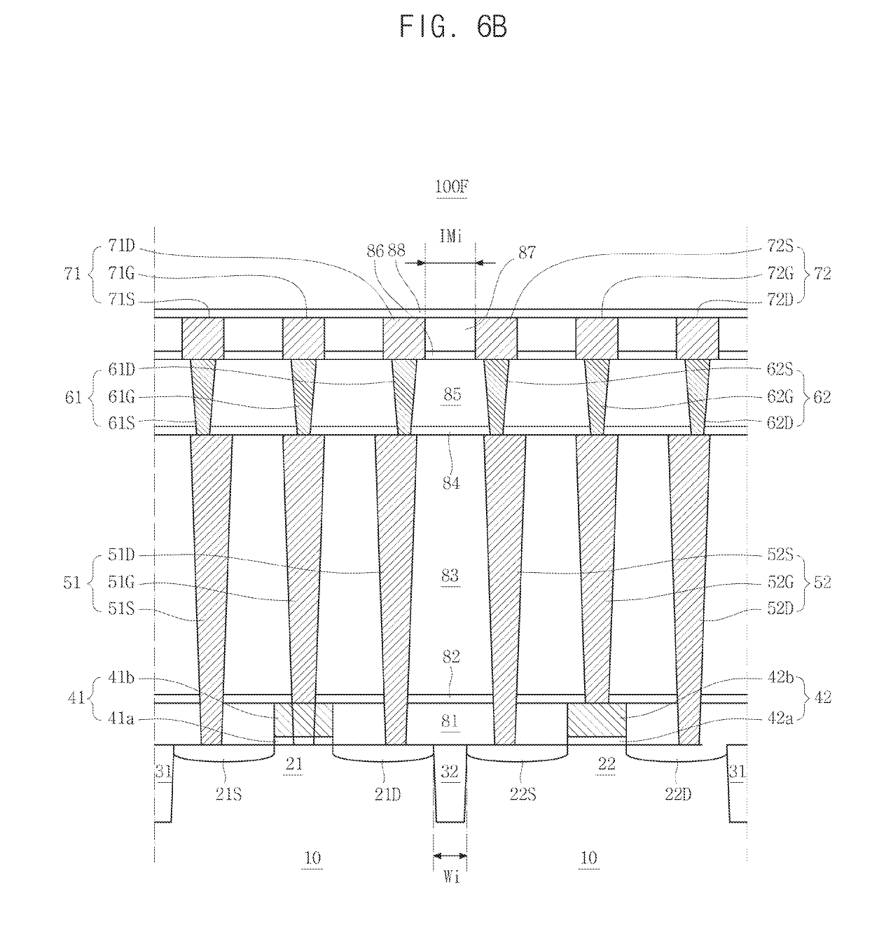

FIG. 6A is a layout of a semiconductor device in accordance with an exemplary embodiment of the inventive concept, and FIG. 6B is a cross sectional view taken along line VI-VI′ of FIG. 6A. Referring to FIGS. 6A and 6B, a semiconductor device 100F in accordance with an exemplary embodiment of the inventive concept may include outer isolation regions 31 and an inter-active isolation region 32 defining first and second active regions 21 and 22 on a substrate 10, first and second gate patterns 41 and 42 across the first and second active regions 21 and 22, first and second contact patterns 51 and 52, first and second stud patterns 61 and 62, and first and second metal lines 71 and 72. In comparison with the semiconductor device 100D shown in FIGS. 4A to 4C, an interval distance between the first active region 21 and the second active region 22, e.g., a width Wi of the inter-active isolation region 32 may be less than an interval distance IMi between the first drain metal line 71D and the second source metal line 72S. For example, Wi<IMi.

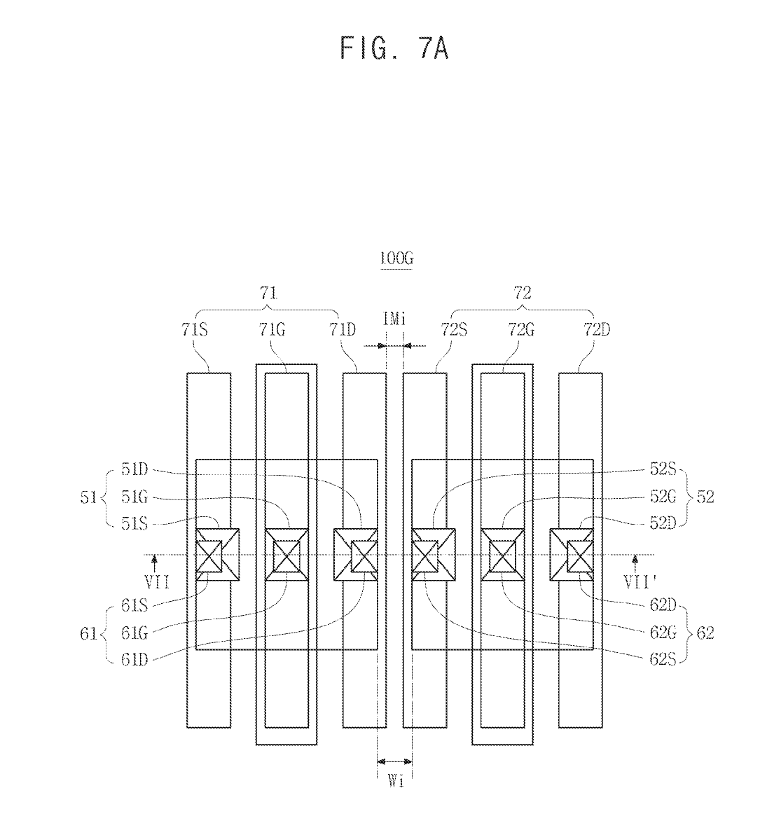

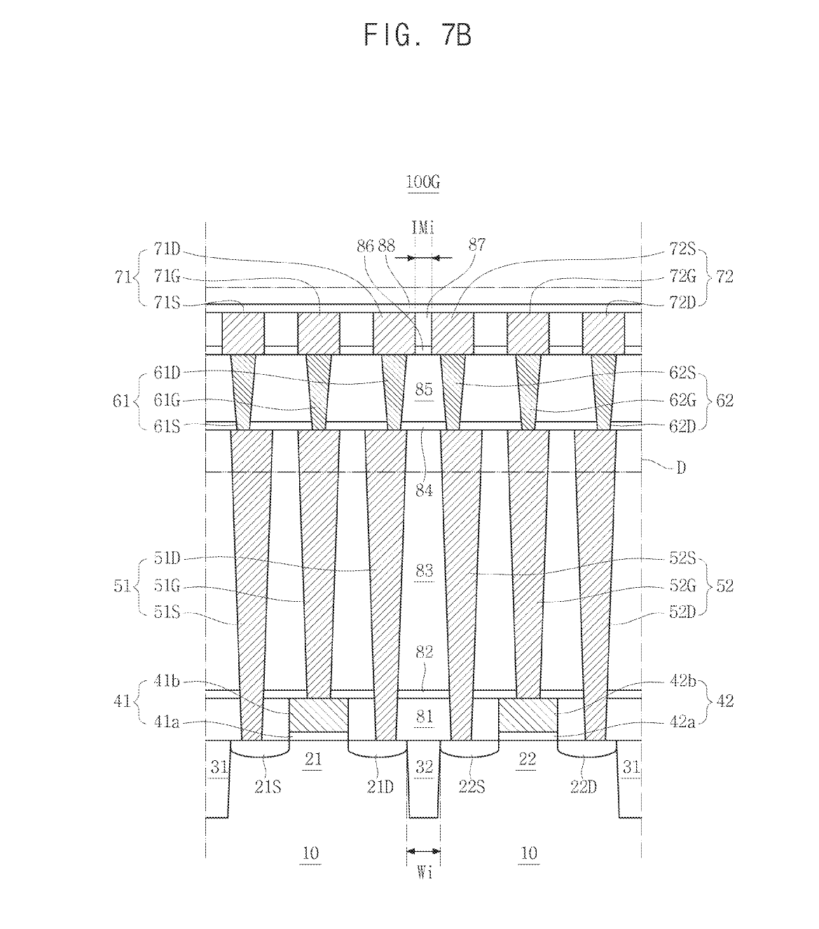

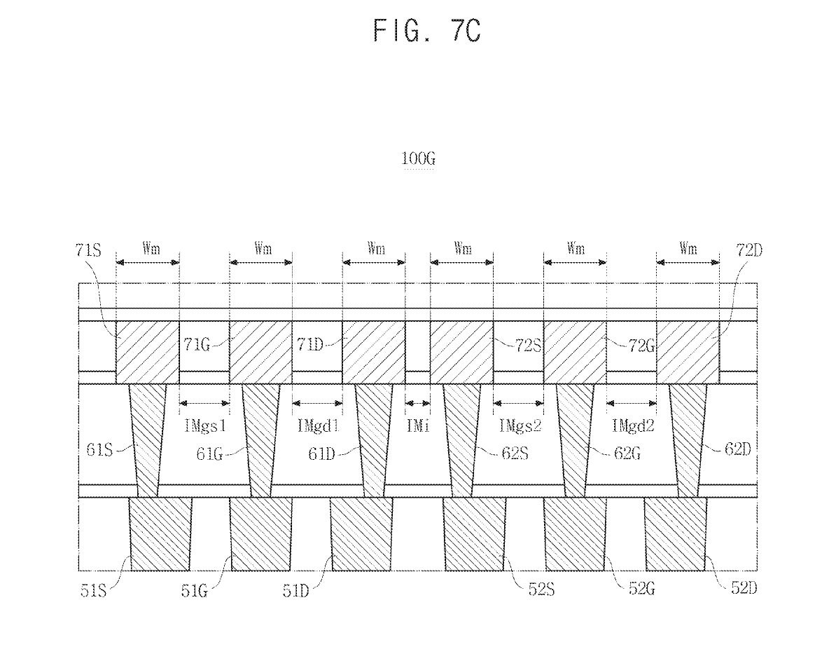

FIG. 7A is a layout of a semiconductor device in accordance with an exemplary embodiment of the inventive concept, FIG. 7B is a cross sectional view taken along line VII-VII′ of FIG. 7A, and FIG. 7C is an enlarged view of area D of FIG. 7B.

Referring to FIGS. 7A, 7B, and 7C, a semiconductor device 100G in accordance with an exemplary embodiment of the inventive concept may include outer isolation regions 31 and an inter-active isolation region 32 defining first and second active regions 21 and 22 on a substrate 10, first and second gate patterns 41 and 42 across the first and second active regions 21 and 22, first and second contact patterns 51 and 52, first and second stud patterns 61 and 62, and first and second metal lines 71 and 72. An interval distance IMgs1 between the first gate metal line 71G and the first source metal line 71S, an interval distance IMgd1 between first gate metal line 71G and the first drain metal line 71D, an interval distance IMgs2 between the second gate metal line 72G and the second source metal line 72S, and an interval distance IMgd2 between the second gate metal line 72G and the second drain metal line 72D may be substantially the same. For example, IMgs1=IMgd1=IMgs2=IMgd2. The interval distances IMgs1, IMgd1, IMgs2, and IMgd2 between the first and second metal lines 71 and 72 may be greater than an interval distance IMi between the first drain metal line 71D and the second source metal line 72S. For example, IMgs1, IMgs2, IMgd1, IMgd2>IMi.

Widths Wm of the first and second metal lines 71 and 72 may be substantially the same. The interval distance IMgs1 between the first gate metal line 71G and the first source metal line 71S, the interval distance IMgd1 between first gate metal line 71G and the first drain metal line 71D, the interval distance IMgs2 between the second gate metal line 72G and the second source metal line 72S, and the interval distance IMgd2 between the second gate metal line 72G and the second drain metal line 72D may be less than the widths Wm of the first and second metal lines 71 and 72. For example, IMgs1, IMgs2, IMgd1, IMgd2<Wm.

An interval distance between the first active region 21 and the second active region 22, e.g., a width Wi of the inter-active isolation region 32 may be greater than the interval distance IMi between the first drain metal line 71D and the second source metal line 72S. For example, Wi>IMi.

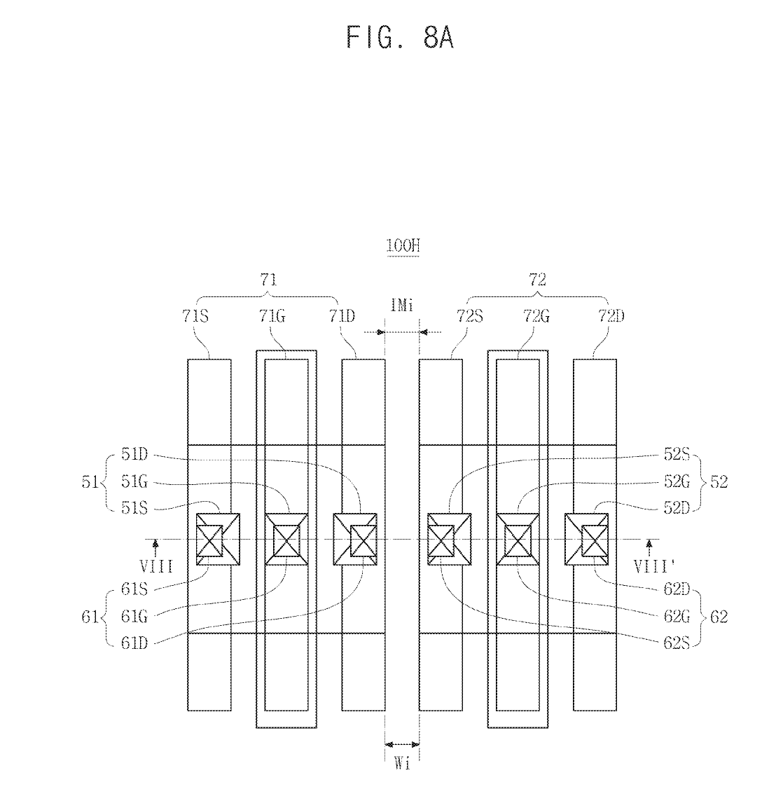

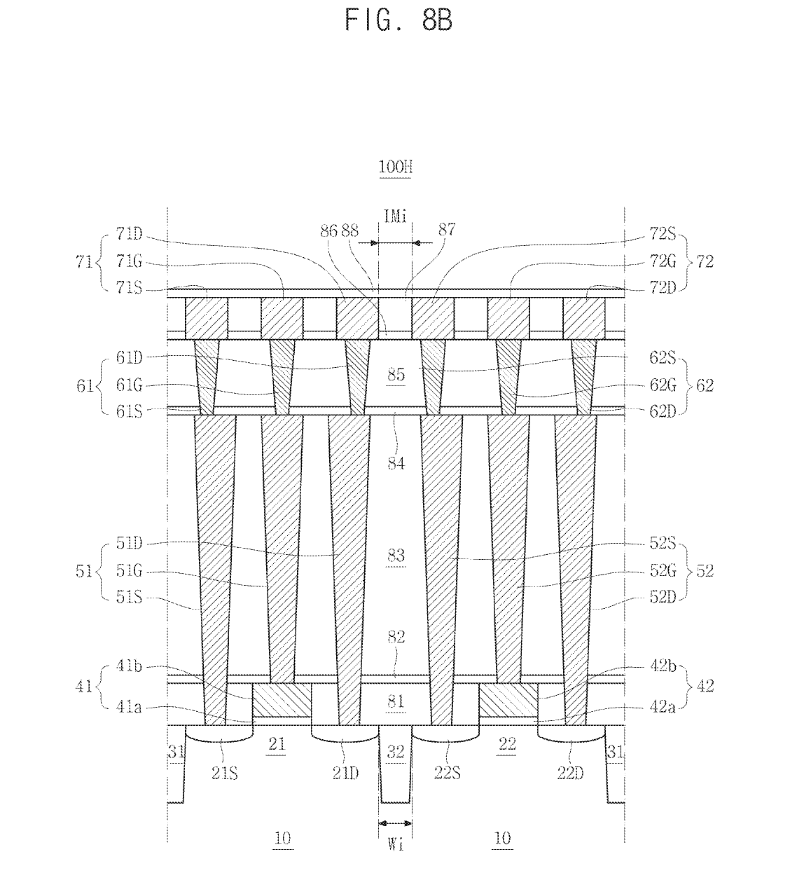

FIG. 8A is a layout of a semiconductor device in accordance with an exemplary embodiment of the inventive concept, and FIG. 8B is a cross sectional view taken along line VIII-VIII′ of FIG. 8A. Referring to FIGS. 8A and 8B, a semiconductor device 100H in accordance with an exemplary embodiment of the inventive concept may include outer isolation regions 31 and inter-active isolation region 32 defining first and second active regions 21 and 22 on a substrate 10, first and second gate patterns 41 and 42 across the first and second active regions 21 and 22, first and second contact patterns 51 and 52, first and second stud patterns 61 and 62, and first and second metal lines 71 and 72. In comparison with the semiconductor device 100G shown in FIGS. 7A to 7C, an interval distance between the first active region 21 and the second active region 22, e.g., a width Wi of the inter-active isolation region 32 may be substantially the same as an interval distance IMi between the first drain metal line 71D and the second source metal line 72S. For example, Wi=IMi.

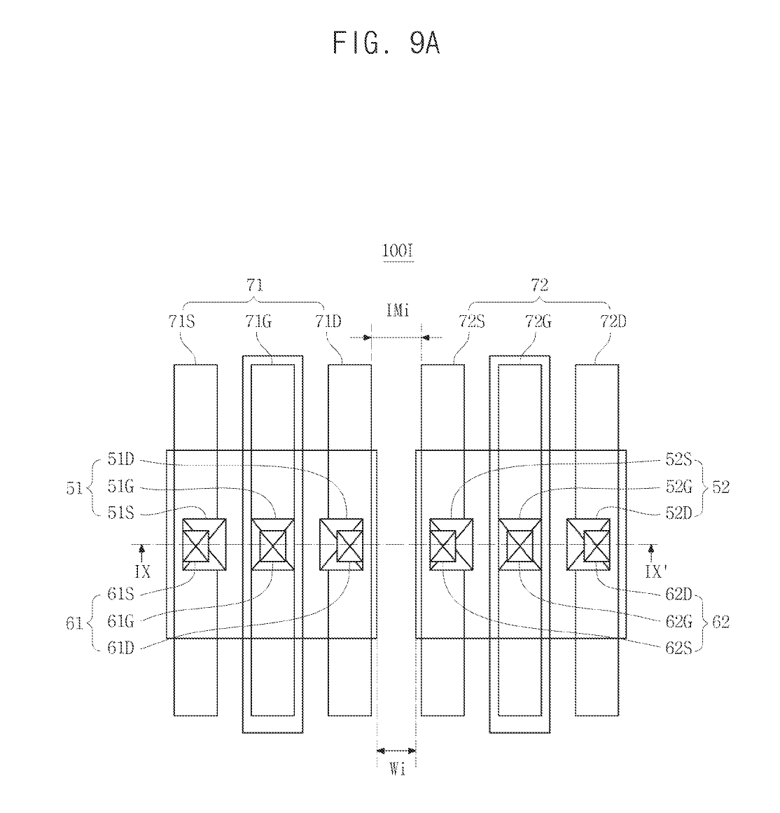

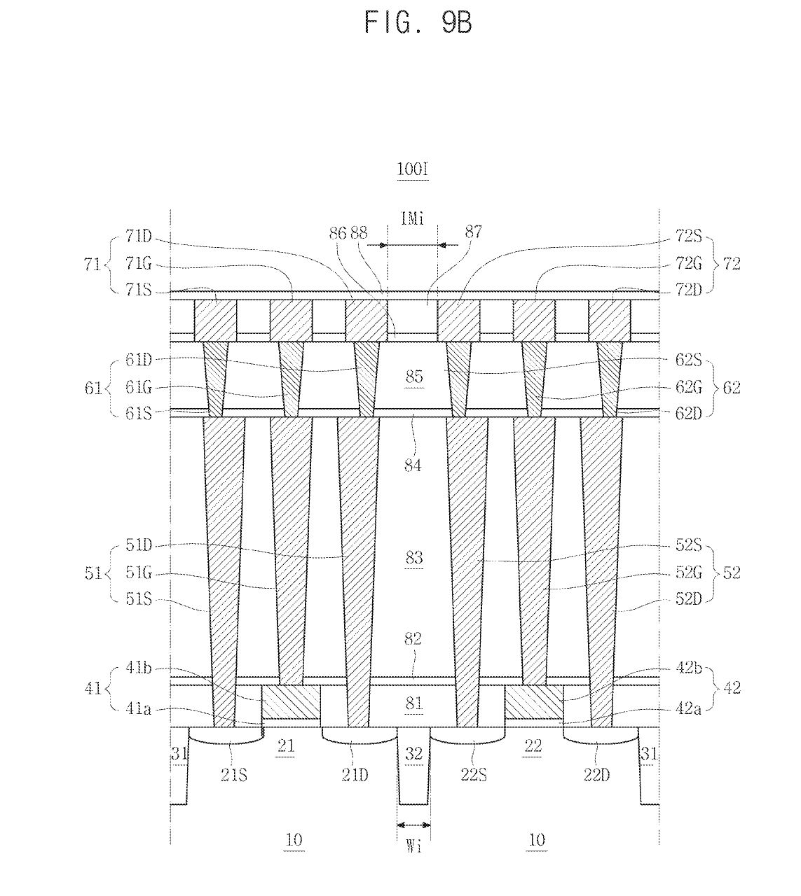

FIG. 9A is a layout of a semiconductor device in accordance with an exemplary embodiment of the inventive concept, and FIG. 9B is a cross sectional view taken along line IX-IX′ of FIG. 9A. Referring to FIGS. 9A and 9B, a semiconductor device 100I in accordance with an exemplary embodiment of the inventive concept may include outer isolation regions 31 and inter-active isolation region 32 defining first and second active regions 21 and 22 on a substrate 10, first and second gate patterns 41 and 42 across the first and second active regions 21 and 22, first and second contact patterns 51 and 52, first and second stud patterns 61 and 62, and first and second metal lines 71 and 72. In comparison with the semiconductor device 100G shown in FIGS. 7A to 7C, an interval distance between the first active region 21 and second active region 22, e.g., a width Wi of the inter-active isolation region 32 may be less than an interval distance IMi between the first drain metal line 71D and the second source metal line 72S. For example, Wi<IMi.

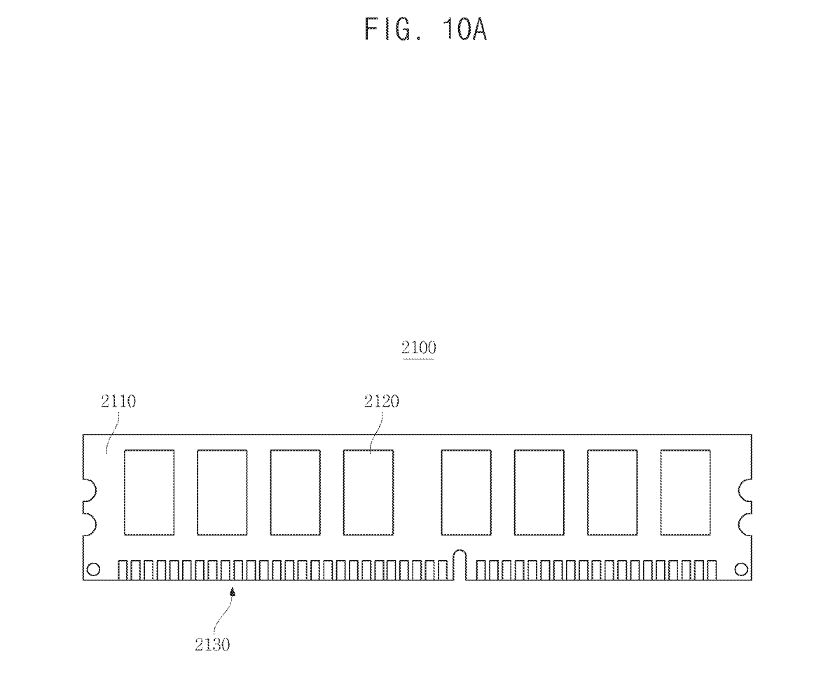

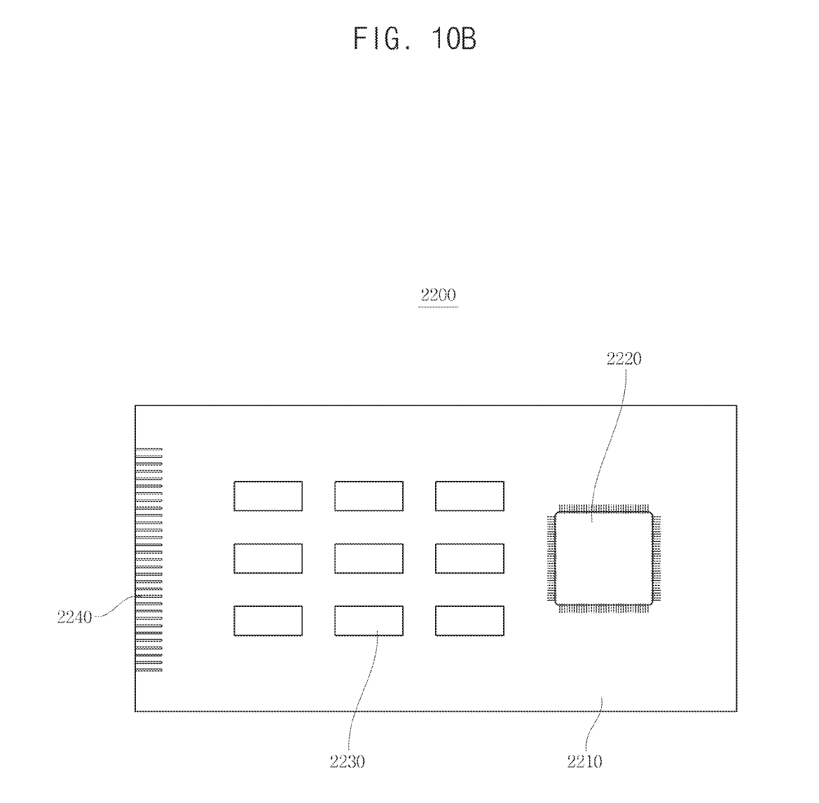

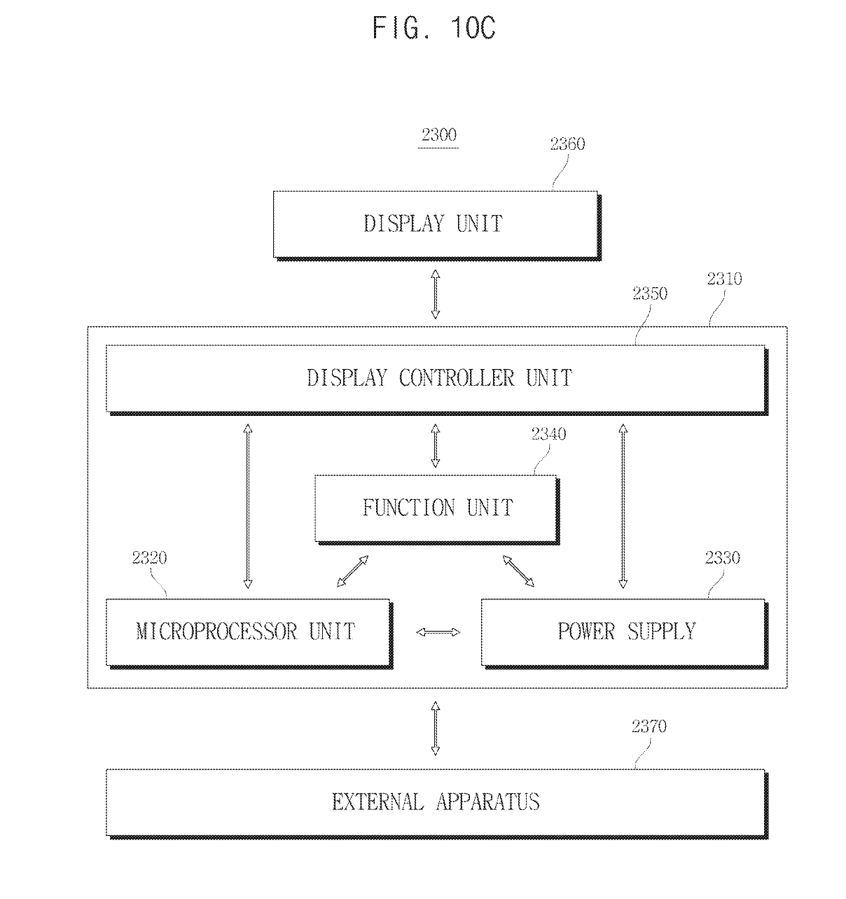

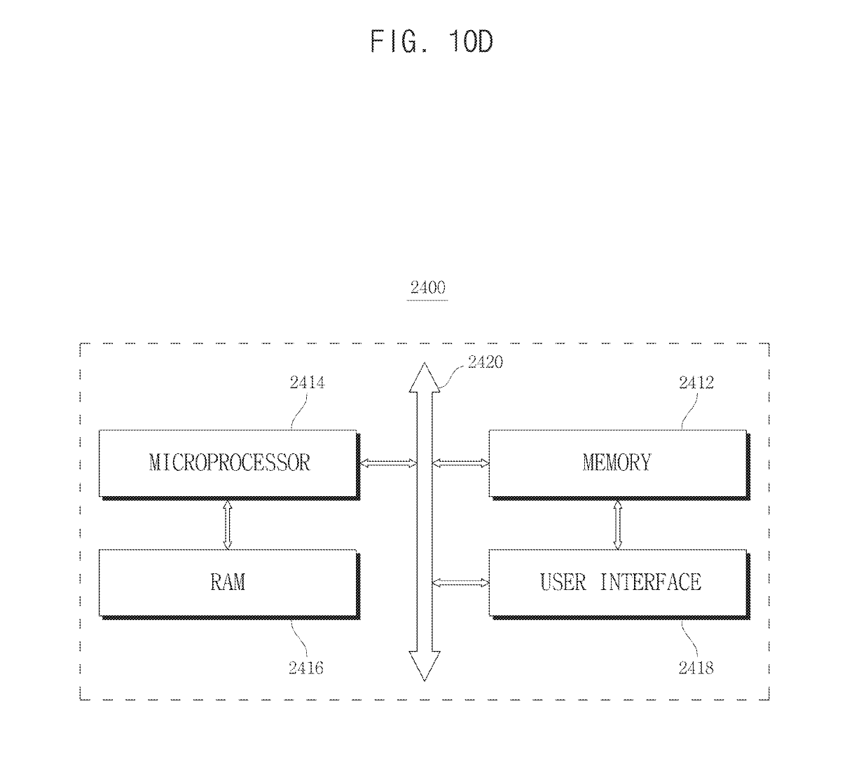

FIG. 10A is a diagram showing a memory module 2100 in accordance with an exemplary embodiment of the inventive concept. Referring to FIG. 10A, the memory module 2100 in accordance with the present embodiment of the inventive concept may include a module substrate 2110, a plurality of memory devices 2120 disposed on the module substrate 2110, and a plurality of terminals 2130 arranged on a side of the module substrate 2110. The module substrate 2110 may include a printed circuit board (PCB). The memory devices 2120 may include at least one of the semiconductor devices 100A to 100I described above in accordance with exemplary embodiments of the inventive concept. The plurality of terminals 2130 may include a metal such as copper. Each of the terminals 2130 may be electrically connected with each of the memory devices 2120.

FIG. 10B is a diagram showing a semiconductor module 2200 in accordance with an exemplary embodiment of the inventive concept. Referring to FIG. 10B, the semiconductor module 2200 in accordance with the present embodiment of the inventive concept may include a processor 2220 mounted on a module substrate 2210, and semiconductor devices 2230. The processor 2220 or the semiconductor devices 2230 may include at least one of the semiconductor devices 100A to 100I described above in accordance with exemplary embodiments of the inventive concept. Conductive input/output terminals 2240 may be disposed on at least one side of the module substrate 2210.

FIG. 10C is a block diagram showing an electronic system 2300 in accordance with an exemplary embodiment of the inventive concept. Referring to FIG. 10C, the electronic system 2300 in accordance with the present embodiment of the inventive concept may include a body 2310, a display unit 2360, and an external apparatus 2370. The body 2310 may include a microprocessor unit 2320, a power supply 2330, a function unit 2340, and/or a display controller unit 2350. The body 2310 may include a system board or motherboard including a PCB and/or a case. The microprocessor unit 2320, the power supply 2330, the function unit 2340, and the display controller unit 2350 may be mounted or disposed on a top surface or an inside of the body 2310. The display unit 2360 may be disposed on the top surface of the body 2310 or an inside/outside of the body 2310. The display unit 2360 may display an image processed by the display controller unit 2350. For example, the display unit 2360 may include a liquid crystal display (LCD), an active matrix organic light emitting diode (AMOLED), or various display panels. The display unit 2360 may include a touch screen. Accordingly, the display unit 2360 may have an input/output function. The power supply 2330 may supply a current or voltage to the microprocessor unit 2320, the function unit 2340, the display controller unit 2350, etc. The power supply 2330 may include a rechargeable battery, a socket for the battery, or a voltage/current converter. The microprocessor unit 2320 may receive a voltage from the power supply 2330 to control the function unit 2340 and the display unit 2360. For example, the microprocessor unit 2320 may include a central processing unit (CPU) or an application processor (AP). The function unit 2340 may include a touchpad, a touchscreen, a volatile/nonvolatile memory, a memory card controller, a camera, a light, an audio and video playback processor, a wireless transmission/reception antenna, a speaker, a microphone, a universal serial bus (USB) port, and other units having various functions. The microprocessor unit 2320 or the function unit 2340 may include at least one of the semiconductor devices 100A to 100I described above in accordance with exemplary embodiments of the inventive concept.

FIG. 10D is a block diagram showing an electronic system 2400 in accordance with an exemplary embodiment of the inventive concept. Referring to FIG. 10D, the electronic system 2400 in accordance with the present embodiment of the inventive concept may include a microprocessor 2414, a memory 2412, and a user interface 2418 which performs data communication using a bus 2420. The microprocessor 2414 may include a CPU or an AP. The electronic system 2400 may further include a random access memory (RAM) 2416 which directly communicates with the microprocessor 2414. The microprocessor 2414 and/or the RAM 2416 may be assembled in a single package. The user interface 2418 may be used to input data to or output data from the electronic system 2400. For example, the user interface 2418 may include a touchpad, a touchscreen, a keyboard, a mouse, a scanner, a voice detector, a cathode ray tube (CRT) monitor, an LCD, an AMOLED, a plasma display panel (PDP), a printer, a light, or various other input/output devices. The memory 2412 may store codes for operating the microprocessor 2414, data processed by the microprocessor 2414, or external input data. The memory 2412 may include a memory controller, a hard disk, or a solid state drive (SSD). The microprocessor 2414, the RAM 2416, and/or the memory 2412 may include at least one of the semiconductor devices 100A to 100I described above in accordance with exemplary embodiments of the inventive concept.

A semiconductor device according to an exemplary embodiment of the inventive concept includes aligned and misaligned contact patterns and stud patterns so that a horizontal pitch of the contact patterns can be reduced.

A size of an active region of a semiconductor device according to an exemplary embodiment of the inventive concept can be reduced as the pitch of the contact patterns is reduced.

Pitches of the metal lines electrically connected with the contact patterns of a semiconductor device according to an exemplary embodiment of the inventive concept can be reduced.

Accordingly, a chip size of a semiconductor device according to an exemplary embodiment of the inventive concept can be reduced and productivity can be increased.

While the inventive concept has been described with reference to exemplary embodiments thereof, it will be understood by those skilled in the art that various changes in form and detail may be made thereto without departing from the scope of the inventive concept as defined by the appended claims.

What is claimed is:

1. A semiconductor device, comprising:
an active region;
a gate pattern on the active region, the active region including a source region at a first side of the gate pattern and a drain region at a second side of the gate pattern;
a gate contact pattern on the gate pattern and a drain contact pattern on the drain region; and
a gate stud pattern on the gate contact pattern and a drain stud pattern on the drain contact pattern,
wherein a distance between a gate contact axis passing through a center portion of the gate contact pattern in a first direction and a drain contact axis passing through a center portion of the drain contact pattern in the first direction is different from a distance between a gate stud axis passing through a center portion of the gate stud pattern in the first direction and a drain stud axis passing through a center portion of the drain stud pattern in the first direction,
wherein the first direction is substantially perpendicular to a surface of the active region on which the gate pattern is disposed.

2. The semiconductor device of claim 1, further comprising:
a gate metal line on the gate stud pattern and a drain metal line on the drain stud pattern, and
wherein a distance between a gate metal axis passing through a center portion of the gate metal line in the first direction and a drain metal axis passing through a center portion of the drain metal line in the first direction is greater than a distance between the gate contact axis and the drain contact axis.

3. The semiconductor device of claim 2, further comprising:
a source contact pattern on the source region; and
a source stud pattern on the source contact pattern,
wherein a distance between the gate contact axis and a source contact axis passing through a center portion of the source contact pattern in the first direction is less than a distance between the gate stud axis and a source stud axis passing through a center portion of the source stud pattern in the first direction.

4. The semiconductor device of claim 3, further comprising:
a source metal line on the source stud pattern,
wherein a distance between the gate metal axis and a source metal axis passing through a center portion of the source metal line in the first direction is greater than a distance between the gate contact axis and the source contact axis.

5. The semiconductor device of claim 4,
wherein a distance between the gate stud axis and the source stud axis is substantially the same as a distance between the gate metal axis and the source metal axis.

6. The semiconductor device of claim 3,
wherein the gate stud axis is substantially aligned with the gate metal axis in the first direction.

7. The semiconductor device of claim 3,
wherein the source contact axis is not aligned with the source stud axis in the first direction.

8. The semiconductor device of claim 3,
wherein the source stud axis is substantially aligned with the source metal axis in the first direction, and the drain stud axis is substantially aligned with the drain metal axis in the first direction.

9. The semiconductor device of claim 2,
wherein a distance between the gate stud axis and the drain stud axis is substantially the same as a distance between the gate metal axis and the drain metal axis.

10. The semiconductor device of claim 1, wherein:
the gate contact axis is substantially aligned with the gate stud axis in the first direction, and
the drain contact axis is not aligned with the drain stud axis in the first direction.

11. A semiconductor device, comprising:
a first active region and a second active region;
a first gate pattern on the first active region including a first source region and a first drain region and a second gate pattern on the second active region including a second source region and a second drain region;
a first gate contact pattern on the first gate pattern, a first source contact pattern on the first source region, a first drain contact pattern on the first drain region, a second gate contact pattern on the second gate pattern, a second source contact pattern on the second source region, and a second drain contact pattern on the second drain region; and
a first gate stud pattern on the first gate contact pattern, a first source stud pattern on the first source contact pattern, a first drain stud pattern on the first drain contact pattern, a second gate stud pattern on the second gate contact pattern, a second source stud pattern on the second source contact pattern, and a second drain stud pattern on the second drain contact pattern,
wherein a distance between a drain contact axis passing through a center portion the first drain contact pattern in a first direction and a source contact axis passing through a center portion of the second source contact pattern in the first direction is different from a distance between a drain stud axis passing through a center portion of the first drain stud pattern in the first direction and a source stud axis passing through a center portion of the second source stud pattern in the first direction,
wherein the first direction is substantially perpendicular to a surface of the first and second active regions on which the first and second gate patterns are disposed.

12. The semiconductor device of claim 11, further comprising:
a first gate metal line on the first gate stud pattern, a first source metal line on the first source stud pattern, a first drain metal line on the first drain stud pattern, a second gate metal line on the second gate stud pattern, a second source metal line on the second source stud pattern, and a second drain metal line on the second drain stud pattern,
wherein a distance between the first drain metal line and the second source metal line is less than a distance between the first active region and the second active region.

13. The semiconductor device of claim 12,
wherein a distance between a drain metal axis passing though a center portion of the first drain metal line in the first direction and a source metal axis passing through a center portion of the second source metal line in the first direction is less than a distance between the drain contact axis and the source contact axis.

14. The semiconductor device of claim 13,
wherein a distance between the drain stud axis and the source stud axis is substantially the same as a distance between the drain metal axis and the source metal axis.

15. The semiconductor device of claim 11,
wherein a distance between a first gate contact axis passing through a center portion of the first gate contact pattern in the first direction and a second gate contact axis passing through a center portion of the second gate contact pattern in the first direction is substantially the same as a distance between a first gate stud axis passing through a center portion of the first gate stud pattern in the first direction and a second gate stud axis passing through a center portion of the second gate stud pattern in the first direction.

16. A semiconductor device, comprising:
a source contact pattern, a gate contact pattern and a drain contact pattern sequentially arranged in a first direction; and
a source stud pattern disposed on the source contact pattern, a gate stud pattern disposed on the gate contact pattern and a drain stud pattern disposed on the drain contact pattern,
wherein a first side of the source contact pattern, a second side of the source contact pattern, a first side of the drain contact pattern and a second side of the drain contact pattern are sequentially arranged in the first direction, and
wherein the source stud pattern is disposed adjacent to the first side of the source contact pattern and the drain stud pattern is disposed adjacent to the second side of the drain contact pattern.

17. The semiconductor device of claim 16, wherein an axis passing through a central portion of the source contact pattern in a second direction substantially perpendicular to the first direction is not aligned with an axis passing through a central portion of the source stud pattern in the second direction.

18. The semiconductor device of claim 16, wherein an axis passing through a central portion of the drain contact pattern in a second direction substantially perpendicular to the first direction is not aligned with an axis passing through a central portion of the drain stud pattern in the second direction.

19. The semiconductor device of claim 16, wherein the semiconductor device is a metal-oxide-semiconductor (MOS) transistor.

20. The semiconductor device of claim 19, wherein the MOS transistor is disposed in a peripheral area of a circuit.
